(19) United States
(12) Patent Application Publication
(10) Pub. No.: US 2023/0335596 A1
(43) Pub. Date: Oct. 19, 2023

(54) SEMICONDUCTOR DEVICE AND MANUFACTURING METHOD THEREOF

(71) Applicant: GaNrich Semiconductor Corporation, Hsinchu City (TW)

(72) Inventors: Chih-Hao Chen, Hsinchu City (TW); Yi-Ru Shen, Yunlin County (TW)

(73) Assignee: GaNrich Semiconductor Corporation, Hsinchu City (TW)

(21) Appl. No.: 18/136,347

(22) Filed: Apr. 19, 2023

(30) Foreign Application Priority Data
Apr. 19, 2022 (CN) 202210412049.2

(51) Int. Cl. H01L 29/778; H01L 29/20; H01L 29/66

(52) U.S. Cl. CPC H01L 29/2003; H01L 29/66462; H01L 29/7786

(57) ABSTRACT

A semiconductor device includes a semiconductor stack, an insulating structure, an electrode structure, and a protective layer. The insulating structure is disposed on the semiconductor stack and includes a first portion. The first portion includes a first opening exposing an inner sidewall of the insulating structure. The electrode structure includes a metal material. The protective layer is disposed between the inner sidewall and the electrode structure, and includes a second opening. The electrode structure is disposed in the first opening and in contact with the protective layer, and the electrode structure is electrically connected to the semiconductor stack through the second opening. The insulating structure includes a first material, and the protective layer includes a second material.

### BACKGROUND OF THE INVENTION

### 1. Field of the Invention

The present disclosure relates to a semiconductor device, and more particularly to a semiconductor device including an electrode structure and a manufacturing method thereof.

### 2. Description of the Prior Art

In semiconductor technology, group III-V compound semiconductor such as gallium nitride (GaN) have the material characteristics of low on-resistance and high breakdown voltage. A high electron mobility transistor (HEMT) made of group III-V compound semiconductor can be used to construct various integrated circuit (IC) devices, such as high-power field effect transistors or high-frequency transistors. A HEMT includes compound semiconductor layers with different energy band gaps, such as a high energy band gap semiconductor layer and a low energy band gap semiconductor layer, which are stacked on each other and thus generate a heterojunction between the semiconductor layers. This heterojunction with discontinuous energy band causes two-dimensional electron gas (2-DEG) to be formed near the heterojunction, and the 2-DEG can be used to transport carriers in the HEMT. Compared with conventional MOSFETs, HEMTs have many attractive characteristics, such as high electron mobility and the ability to transmit signals at high-frequency, because HEMTs use 2-DEG instead of a doped region as the carrier channel of MOSFETs.

For conventional HEMTs, an electrode structure is used to be electrically connected to a semiconductor layer below the electrode structure, so that current can flow between the electrode structure and the semiconductor layer. However, power loss often occurs when current flows through the electrode structure and the semiconductor layer, which reduces the performance in electrical characteristic of the device.

### SUMMARY OF THE INVENTION

In view of this, it is necessary to provide an improved semiconductor device to improve the defects of conventional semiconductor devices.

According to some embodiments of the present disclosure, a semiconductor device is disclosed, which includes a semiconductor stack, an insulating structure, an electrode structure, and a protective layer. The insulating structure is disposed on the semiconductor stack and includes a first portion. The first portion includes a first opening exposing an inner sidewall of the insulating structure. The protective layer is disposed between the inner sidewall and the electrode structure, and includes a second opening. The electrode structure is disposed in the first opening and in contact with the protective layer, and the electrode structure is electrically connected to the semiconductor stack through the second opening. The electrode structure includes a metal material, the insulating structure includes a first material, and the protective layer includes a second material.

According to some embodiments of the present disclosure, a method of manufacturing a semiconductor device is disclosed, which includes the following steps. A semiconductor stack is provided. Then, a first insulating layer is disposed on the semiconductor stack, wherein the first insulating layer includes a first opening exposing an inner sidewall of the first insulating layer. A protective layer is filled into the first opening to cover the inner sidewall. Subsequently, the protective layer is etched to remove a portion of the protective layer in the first opening to form a second opening. Then, an electrode structure is disposed so that the protective layer is sandwiched between the electrode structure and the inner sidewall. A heat treatment process is then performed at a treatment temperature. The first insulating layer includes a first material, the protective layer includes a second material, and the electrode structure includes a metal material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to one embodiment of the present disclosure, where the semiconductor device includes a protective layer disposed between an electrode structure and an insulating structure.

FIG. 2 is a schematic cross-sectional view of a partial region of a semiconductor device according to an alternative embodiment of the present disclosure.

FIG. 3 to FIG. 9 are schematic cross-sectional views of a method of manufacturing a semiconductor device according to one embodiment of the present disclosure.

FIG. 10 is a flowchart of a method of manufacturing a semiconductor device according to one embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “over,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another element, component, region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

In the present disclosure, a “group III-V semiconductor” refers to a compound semiconductor that includes at least one group III element and at least one group V element, where group III element may be boron (B), aluminum (Al), gallium (Ga) or indium (In), and group V element may be nitrogen (N), phosphorous (P), arsenic (As), or antimony (Sb). Furthermore, the group III-V semiconductor may refer to binary semiconductor, ternary semiconductor, quaternary semiconductor, compound semiconductor beyond quaternary semiconductor, or a combination thereof, but not limited thereto. For example, the group III-V semiconductor is binary semiconductor, such as aluminum nitride (AlN), gallium nitride (GaN), indium phosphide (InP), aluminum arsenide (AlAs), or gallium arsenide (GaAs), ternary semiconductor, such as aluminum gallium nitride (AlGaN), indium gallium nitride (InGaN), gallium indium phosphide (GaInP), aluminum gallium arsenide (AlGaAs), indium aluminum arsenide (InAlAs), or indium gallium arsenide (InGaAs), or quaternary semiconductor such as indium aluminum gallium nitride (InAlGaN). Besides, based on different requirements, group III-V semiconductor may contain dopants to become semiconductor with specific conductivity type, such as n-type or p-type.

Although the disclosure is described with respect to specific embodiments, the principles of the invention, as defined by the claims appended herein, can obviously be applied beyond the specifically described embodiments of the invention described herein. Moreover, in the description of the present disclosure, certain details have been left out in order to not obscure the inventive aspects of the disclosure. The details left out are within the knowledge of a person of ordinary skill in the art.

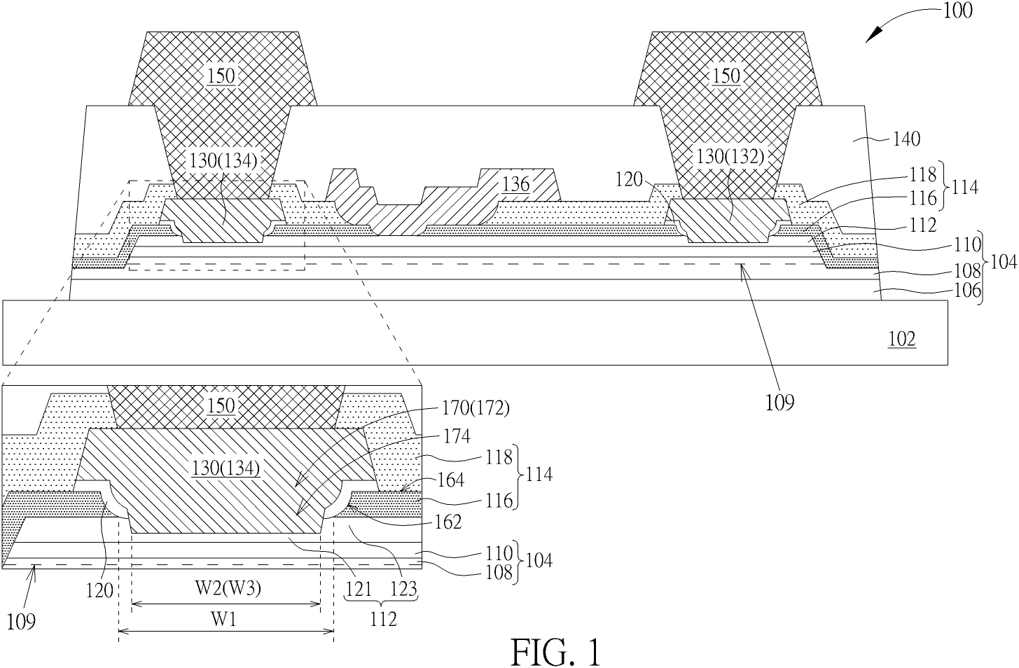

FIG. 1 is a schematic cross-sectional view of a semiconductor device according to one embodiment of the present disclosure. Referring to FIG. 1, a semiconductor device 100, such as a high electron mobility transistor, includes a semiconductor stack 104, an insulating structure 114, an electrode structure 130, and a protective layer 120. The insulating structure 114 is disposed on the semiconductor stack 104 and includes a first portion 116. The first portion 116 includes a first opening 170, and the first opening 170 exposes an inner sidewall 162 of the insulating structure 114. The protective layer 120 is disposed between the inner sidewall 162 and the electrode structure 130, and the protective layer 120 includes a second opening 172. The electrode structure 130 disposed in the first opening 170 is in contact with the protective layer 120 and is electrically connected to the semiconductor stack 104 through the second opening 172. The electrode structure 130 includes a metal material, the insulating structure 114 includes a first material, and the protective layer 120 includes a second material. The reaction temperature between the second material and the metal material is higher than the reaction temperature between the first material and the metal material. In other words, the first material and the metal material are capable of reacting at a first reaction temperature, and the second material and the metal material are capable of reacting at a second reaction temperature. The second reaction temperature is higher than the first reaction temperature, and a temperature of the heat treatment process is higher than the first reaction temperature and lower than the second reaction temperature.

According to some embodiments of the present disclosure, the protective layer 120 is disposed between the electrode structure 130 and the first portion 116 of the insulating structure 114, and the second material of the protective layer 120 is selected from the material whose reaction temperature with the metal material of the electrode structure 130 is higher than the reaction temperature between the first material of the insulating structure 114 and the metal material of the electrode structure 130. The protective layer 120 made of the above selected material can prevent the electrode structure 130 from directly contacting the first portion 116 of the insulating structure 114, thus avoiding unnecessary chemical reactions (such as oxidation reactions) between the electrode structure 130 and the insulating structure 114. In this way, the increase in contact resistance between the electrode structure 130 and the underlying semiconductor layer can be avoided, which is caused by the chemical reactions between the electrode structure 130 and the insulating structure 114.

In addition to the above components and layers, the semiconductor device 100 may further include other optional components and layers. The components and layers of the semiconductor device 100 are further described below.

Referring to FIG. 1, the semiconductor device 100 includes a substrate 102, which may be an epitaxial substrate (such as a bulk silicon substrate, a silicon carbide (SiC) substrate, an aluminum nitride (AlN) substrate, or a sapphire substrate), a ceramic substrate, or a semiconductor-on-insulator substrate (such as a silicon-on-insulator (SOI) substrate or germanium-on-insulator (GOI) substrate), but not limited thereto. According to some embodiments of the present disclosure, the whole or the surface of the substrate 102 can be electrically insulating, thus further avoiding unnecessary electrical connection between structures arranged above and below the substrate 102, respectively. However, according to some embodiments of the present disclosure, the substrate 102 can also have conductivity and is not limited to an insulating substrate. According to some embodiments of the present disclosure, the substrate 102 can also be removed, so that the bottom surface of the semiconductor stack 104 is exposed.

The semiconductor stack 104 is disposed on the substrate 102 and includes a plurality of group III-V semiconductor layers. For example, the semiconductor stack 104 includes a buffer layer 106, a channel layer 108, and a barrier layer 110 stacked in sequence from bottom to top. The buffer layer 106 can be used to reduce the degree of stress or lattice mismatch between the substrate 102 and the semiconductor stack 104. The buffer layer 106 can include a plurality of group III-V sub-semiconductors, which can form a composition ratio gradient layer or a super lattice structure, wherein the composition ratio gradient layer means that the composition ratio of the semiconductor sub-layers adjacent to each other can continuously change along a certain direction, such as aluminum gallium nitride (AlₓGa₍₁₋ₓ₎N) with a gradually changed composition ratio, and the value of x decreases in a continuous or stepwise manner along the direction away from the substrate 102. The super lattice structure includes alternately stacked semiconductor sub-layers with slightly different composition ratios, and these semiconductor sub-layers are adjacent to each other and appear in pairs (for example, paired Alₓ₁Ga₍₁₋ₓ₁₎N and Alₓ₂Ga₍₁₋ₓ₂₎N, 0≤X1≤0.2, 0.2≤X2≤0.5) as the smallest repeating unit in the super lattice structure.

The channel layer 108 is disposed on the substrate 102, for example, disposed on the buffer layer 106. The channel layer 108 may include one or more group III-V semiconductor layers, and the compositions of the group III-V semiconductor layers may be GaN, AlGaN, InGaN or InAlGaN, but not limited thereto. For example, the channel layer 108 is an undoped group III-V semiconductor, such as undoped-GaN (u-GaN).

The barrier layer 110 is disposed on the channel layer 108. The barrier layer 110 may include one or more group III-V semiconductor layers, and the composition of the group III-V semiconductor layers of the barrier layer 110 may be different from that of the channel layer 108. For example, the material of the barrier layer 110 may include a material with a larger energy band gap than an energy band gap of the material of the channel layer 108, such as AlN, AlₓGa₍₁₋ₓ₎N (0 < x < 1), or a combination thereof. According to one embodiment of the present disclosure, the barrier layer 110 may be an n-type group III-V semiconductor, such as an intrinsic n-type AlGaN layer, but not limited thereto.

Because there is an energy band gap discontinuity between the channel layer 108 and the barrier layer 110, a potential well can be formed in the channel layer 108 near the heterojunction between the channel layer 108 and the barrier layer 110 by stacking the channel layer 108 and the barrier layer 110 with each other. Electrons can be accumulated in the potential well due to the piezoelectric effect, thus producing a sheet with high electron mobility, i.e., two-dimensional electron gas (2-DEG) region 109.

According to different requirements, the semiconductor stack 104 may include other semiconductor layers such as group III-V semiconductor layers, which are disposed between the substrate 102 and the buffer layer 106 or between the buffer layer 106 and the barrier layer 110. For example, the semiconductor stack 104 may further include a nucleation layer (not shown) or a high resistance layer (not shown), wherein the nucleation layer is a group III-V semiconductor layer, such as AlN or other nitride semiconductor layer, which can make the semiconductor layers disposed above the nucleation layer have better crystal quality. The high-resistance layer such as carbon-doped gallium nitride (c-GaN) is disposed on the buffer layer 106, and the electrical resistivity of the high-resistance layer is higher than the electrical resistivity of other layers, thus preventing the current leakage between the semiconductor layers disposed above the high-resistance layer and the substrate 102.

The cap layer 112 is disposed on the semiconductor stack 104 and between the insulating structure 114 and the semiconductor stack 104. The cap layer 112 can be used to eliminate or reduce the surface defects existing on the surface of the barrier layer 110, thereby improving the electron mobility of the two-dimensional electron gas region 109. The cap layer 112 can also be used to protect the underlying semiconductor stack 104 from the damages caused during an etching process, such as an etching process for forming a contact opening. Referring to the enlarged diagram of a partial region at the bottom of FIG. 1, the cap layer 112 includes a recess portion 121 and an extension portion 123, and the extension portion 123 is disposed at the periphery of the recess portion 121. The bottom surface of the recess portion 121 has a width, such as a third width W3. The extension portion 123 includes insulating nitride material, such as silicon nitride (SiNₓ), and the material of the recess portion 121 may include the same elements as those of the material of the extension portion 123, such as silicon and nitrogen. However, the recess portion 121 may include additional conductive compositions, such as aluminum, tungsten, titanium, vanadium, zirconium, tantalum, other metal compositions, or an alloy thereof, so that the conductivity of the recess portion 121 as a whole is higher than the conductivity of the extension portion 123 (that is, the electrical resistivity of the extension portion 123 is higher than the electrical resistivity of the recess portion 121).

The insulating structure 114 is disposed on the cap layer 112. In addition to the first portion 116, the insulating structure 114 further includes a second portion 118 disposed on the first portion 116. Referring to the enlarged diagram of a partial region at the bottom of FIG. 1, the bottom surface of the first opening 170 of the first portion 116 has a first width W1. The inner sidewall 162 of the first portion 116 is an inclined surface or an upward concave surface, and the first portion 116 further includes a top surface 164 (or an upper surface). The material of the first portion 116 (i.e., the first material) and the material of the second portion 118 are different from the material of the cap layer 112. The first material of the first portion 116 may include an insulating oxide material, such as silicon oxide. In one embodiment, the first material of the first portion 116 may include oxynitride, such as silicon oxynitride, as an insulating oxide material or an insulating nitride material. The material of the second portion 118 may also include insulating oxide material the same as or different from the first material.

6 The protective layer 120 is disposed on the first portion 116 of the insulating structure 114, so that a portion of the protective layer 120 fills the first opening 170 of the first portion 116 and conformally covers the inner sidewall 162 of the first portion 116. In certain embodiments, other portions of the protective layer 120 can extend out of the first opening 170 and conformally cover a portion of the top surface 164 of the first portion 116. Two opposite protective layers 120 define a second opening 172, and the bottom of the second opening 172 has a second width W2. Although the protective layers 120 shown in FIG. 1 are separated from each other, when viewed from a top-down perspective, the two opposite protective layers 120 are connected to each other as a continuous layer and surround the second opening 172 together. The second material of the protective layer 120 may include nitride material. In one embodiment, the second material of the protective layer 120 may include nitride material, such as titanium nitride, vanadium nitride, zirconium nitride, or tantalum nitride of metal material. In one embodiment, the second material may be a single-layer or a multi-layer structure, such as Ti/TiN or other stacked structures.

Electrode structures 130, such as a drain electrode 132 and a source electrode 134, are disposed on the cap layer 112. The electrode structures 130 fill not only the second opening 172 but also a recess 174 in the cap layer 104, so as to be electrically connected to the underlying semiconductor layers, such as the channel layer 108 and the barrier layer 110. The electrode structures 130 can be ohmic contact with the underlying cap layer 112 and some layers (such as the channel layer 108) in the semiconductor stack 104. The material of the electrode structure 130 may be a low-impedance metal, such as aluminum, but not limited thereto.

The arrangement of the cap layer 112, the insulating structure 114 (including the first portion 116 and the second portion 118), the protective layer 120, and the electrode structure 130 is further described as follows. Referring to the enlarged diagram of the partial region at the bottom of FIG. 1, the recess portion 121 of the cap layer 112 is located below the first opening 170 of the first portion 116 and the second opening 172 of the protective layer 120 and overlaps the second opening 172, so that the recess portion 121 of the cap layer 112 is exposed from the bottom surface of the second opening 172. The protective layer 120 is sandwiched between the electrode structure 130 and the first portion 116, so that the electrode structure 130 is completely separated from and not in direct contact with the first portion 116 of the insulating structure 114. In addition, the protective layer 120 extending to a region outside the first opening 170 is disposed between a top surface 164 of the first portion 116 of the insulating structure 114 and the electrode structure 130. The second portion 118 covers the top surface 164 of the first portion 116, the upper sidewall and the top surface of the protective layer 120, and the upper sidewall and the top surface of the electrode structure 130.

Regarding the material of the first portion 116 of the insulating structure 114, the material of the protective layer 120, and the material of the electrode structure 130, in one embodiment, when the material of the electrode structure 130 is easily oxidized (e.g., metal with a work function from 4.0 eV to 4.4 eV), the electrode structure 130 is prone to react, such as chemical reactions (e.g., oxidation reactions), with nonmetallic element in the material of the first portion 116, resulting in products with low conductivity (e.g., metal oxides). In order to avoid the product with low conductivity, the protective layer 120 is disposed between the electrode structure 130 and the first portion 116. The second material of the protective layer 120 has a characterize which is more difficult to react with the metal material of the electrode structure 130 than that of the first material of the insulating structure 114. The reaction temperature between the second material of the protective layer 120 and the electrode structure 130 is higher than the reaction temperature between the first material of the insulating structure 114 and the electrode structure 130. So the protective layer 120 can avoid the electrode structure 130 from directly contacting the first portion 116 of the insulating structure 114 and reacting with the insulating structure 114. In this case, the chemical reaction between the electrode structure 130 and the first portion 116 of the adjacent insulating structure 114 can be avoided, thereby preventing the electrical resistivity of the electrode structure 130 to increase. In some embodiments, the reaction temperature between the second material of the protective layer 120 and the electrode structure 130 is high enough to the extent that no reaction occurs between the second material of the protective layer 120 and the metal material of the electrode structure 130. In this case, a chemical reaction between the electrode structure 130 directly contacting the first portion 116 of the insulating structure 114 can be avoided.

The semiconductor device 100 may include an additional conductive layer such as a gate electrode 136 disposed on one side of the electrode structure 130, for example, between two electrode structures 130. The gate electrode 136 is disposed on the cap layer 112 and filled into the contact opening in the insulating structure 114, so that a portion of the gate electrode 136 penetrates through the first portion 116 and the second portion 118 of the insulating structure 114. Furthermore, the gate electrode 136 is an asymmetric structure and extends toward the drain electrode 132. The extended portion and the corresponding end of the gate electrode 136 cover the first portion 116 and the second portion 118 of the insulating structure 114 and can serve as a field plate of the semiconductor device 100 to control the electric field distribution and/or the peak value of the electric field in the underlying semiconductor stack 104.

According to some embodiments of the present disclosure, the gate electrode 136, the cap layer 112 located directly below the gate electrode 136, and the channel layer 108 located below the gate electrode 136 can constitute a metal-insulator-semiconductor (MIS) capacitor structure. In this case, during the operation of the semiconductor device 100, the current can be blocked by the cap layer 112 and does not flow between the gate electrode 136 and the channel layer 108. In addition, according to some embodiments of the present disclosure, the gate electrode 136 can penetrate through the cap layer 112 and directly contact the barrier layer 110 to form a Schottky contact structure with the barrier layer 110. In this case, the current does not easily flow through the Schottky contact junction between the gate electrode 136 and the barrier layer 110 during the operation of the semiconductor device 100.

A third insulating layer, such as a dielectric interlayer 140, is disposed on the insulating structure 114 and the gate electrode 136. The dielectric interlayer 140 includes contact openings to expose the underlying drain electrode 132 and source electrode 134, respectively.

At least two bond pad structures 150 are disposed in the contact openings in the dielectric interlayer 140 to be electrically connected to the drain electrode 132 and the source electrode 134, respectively. The top surfaces of the bond pad structures 150 are exposed from the dielectric interlayer 140 to serve as regions through which the semiconductor device 100 and external devices are electrically connected. The semiconductor device 100 may also include another bond pad structure (not shown) electrically connected to an electrode structure (such as the gate electrode 136). The material of the dielectric interlayer 140 includes insulating materials, such as Si₃N₄, AlN, or other insulating nitride materials, Al₂O₃, SiO₂ or other insulating oxide materials, or SiON as an insulating oxide material or an insulating nitride material, but not limited thereto.

In addition to the above embodiments, the semiconductor device of the present disclosure may include other embodiments and is not limited to the foregoing embodiments. In the following paragraphs, various modifications and variations about semiconductor devices are disclosed and the description below is mainly focused on differences among these embodiments. In addition, the present disclosure may repeat reference numerals and/or letters in the various modifications and variations. This repetition is for the purpose of simplicity and clarity and does not in itself dictate a relationship between the various embodiments and/or configurations discussed.

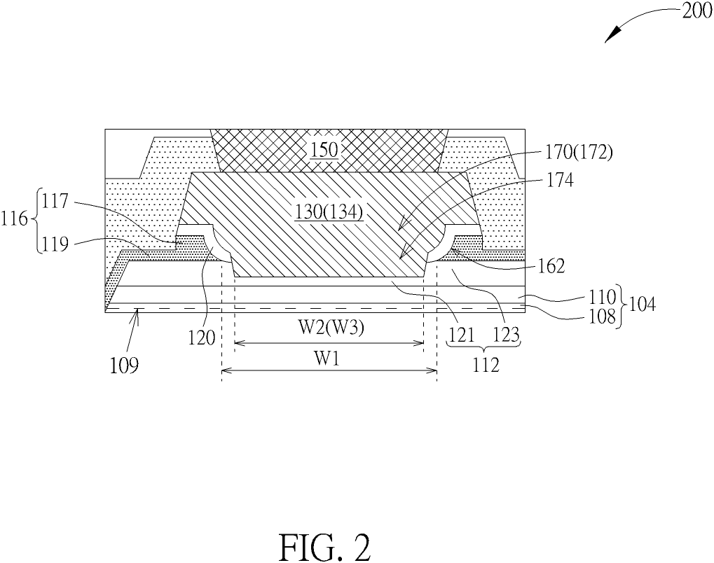

FIG. 2 is a schematic cross-sectional view of a partial region of a semiconductor device according to an alternative embodiment of the present disclosure. Referring to FIG. 2, the structure of a semiconductor device 200 in FIG. 2 is similar to the structure of the semiconductor device 100 in FIG. 1. The main difference between the two embodiments is that the first portion 116 of the insulating structure in FIG. 2 further includes an end portion 117 and an extension portion 119. The end portion 117 is disposed between the semiconductor stack 104 and the protective layer 120, and the extension portion 119 extends from one side of the end portion 117. The top surface of the end portion 117 is higher than the top surface of the extension portion 119. In this case, even if the top surface of the end portion 117 is higher than the top surface of the extension portion 119, the extension portion 119 can still cover the top surface and sidewall of the semiconductor stack 104.

In order to enable one of ordinary skill in the art to implement the disclosed invention, the method of manufacturing the semiconductor device is further described in detail below.

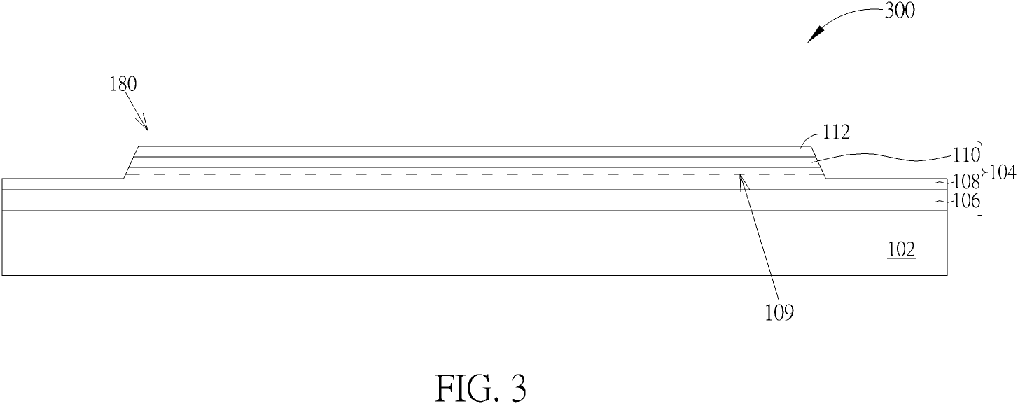

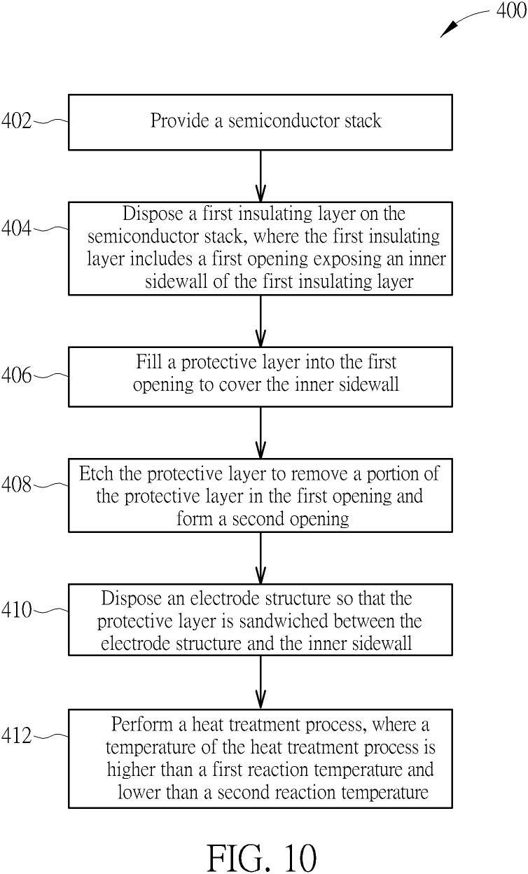

FIG. 3 to FIG. 9 are schematic cross-sectional views of a method of manufacturing a semiconductor device according to one embodiment of the present disclosure. FIG. 10 is a flowchart of a method of manufacturing a semiconductor device according to one embodiment of the present disclosure. Referring to a cross-sectional view 300 of FIG. 3, in step 402 of a manufacturing method 400, a semiconductor stack is provided. For example, a semiconductor stack 104 disposed on a substrate 102 is provided. Each of the semiconductor layers in the semiconductor stack 104 is sequentially formed on the surface of the substrate 102 by epitaxial or deposition processes. For example, molecular-beam epitaxy (MBE), metal-organic chemical vapor deposition (MOCVD), hydride vapor phase epitaxy (HVPE), atomic layer deposition (ALD), or other suitable methods may be performed to form each of the semiconductor layers of the semiconductor stack 104. After the semiconductor stack 104 is formed, a cap layer 112 is formed on the semiconductor stack 104 by, for example, a vapor deposition process. In the subsequent etching process, the cap layer 112 serves as an etching stop layer. In addition, the cap layer 112 can also serve as a passivation layer to protect the underlying semiconductor stack 104. For example, the material of the cap layer 112 includes insulating nitride material (such as silicon nitride (Si₃N₄), aluminum nitride (AlN)), insulating oxide material (such as aluminum oxide (Al₂O₃), silicon oxide (SiOₓ)), semiconductor material (such as gallium nitride (GaN)), or silicon oxynitride (SiON) as an insulating oxide material or an insulating nitride material, but not limited thereto. Then, an etching process is performed to remove a portion of the cap layer 112 and a portion of the semiconductor stack 104, so as to form a protruding mesa region 180, which can be used to accommodate a gate electrode, a source electrode and a drain electrode of the semiconductor device.

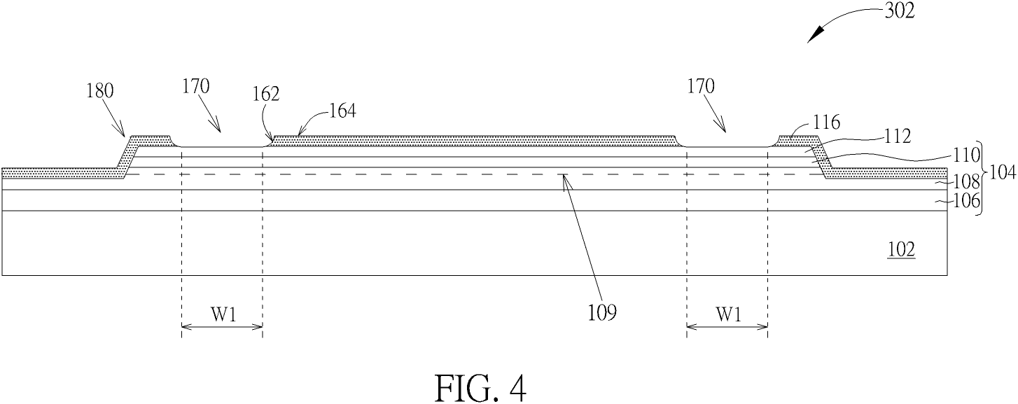

Next, in step 404 of the manufacturing method 400, a first insulating layer is disposed on the semiconductor stack, where the first insulating layer includes a first opening, and the first opening exposes the inner sidewall of the first insulating structure. Referring to the cross-sectional view 302 of FIG. 4, the first insulating layer such as a first portion 116 covering the semiconductor stack 104 and the cap layer 112 is formed by performing a deposition process, such as a vapor deposition process. The material of the first portion 116 is different from the material of the cap layer 112. For example, the material of the first portion 116 includes silicon oxide (SiOₓ), aluminum oxide (Al₂O₃) or other insulating oxide material, silicon nitride (Si₃N₄), or other insulating nitride material, or silicon oxynitride (SiON) as an insulating oxide material or an insulating nitride material, but not limited thereto. In addition, the first portion 116 is not limited to a single-layer structure, but can also be a multi-layer stacked structure. After the first portion 116 is formed, a partial region of the first portion 116 is etched through to form the first opening 170. The bottom of the first opening 170 has a first width W1 and exposes the inner sidewall 162 of the first insulating layer (such as the first portion 116) and the underlying cap layer 112.

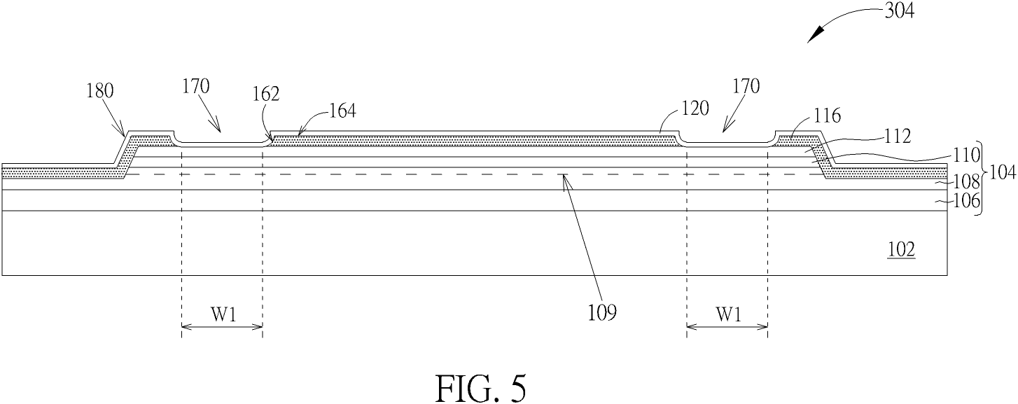

Then, in step 406 of the manufacturing method 400, a protective layer is filled into the first opening to cover the inner sidewall. Referring to the cross-sectional view 304 of FIG. 5, the protective layer 120 is conformally formed on the surface of the first portion 116 to cover the inner sidewall 162 and the top surface 164 of the first portion 116, and the protective layer 120 is filled into the first opening 170. Since the thickness of the first portion 116 is greater than the thickness of the protective layer 120, the first opening 170 is not filled up by the protective layer 120.

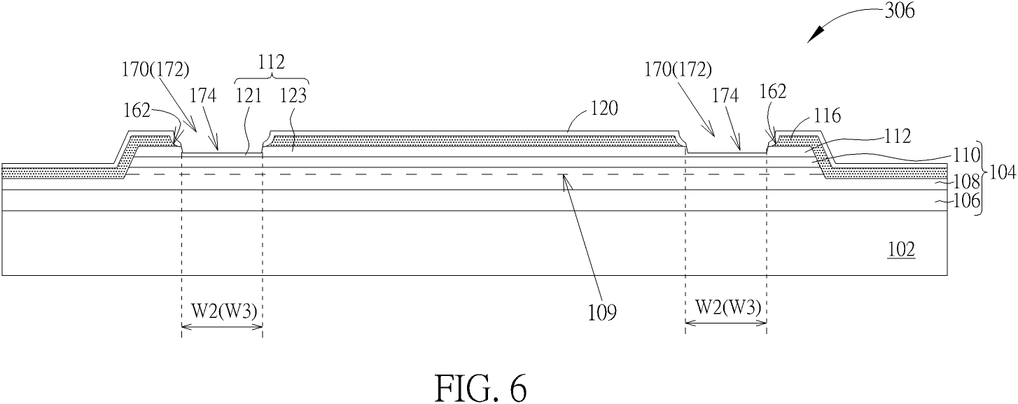

Next, in step 408 of the manufacturing method 400, the protective layer is etched to remove the protective layer located in the first opening. Referring to a cross-sectional view 306 of FIG. 6, the protective layer 120 at the bottom surface of the first opening 170 is removed by photolithography and etching processes, and a portion of the protective layer 120 still covers the inner sidewall 162 of the first portion 116. In addition, a portion of the cap layer 112 can be removed in this step to form a recess 174 in the cap layer 112. At this time, the cap layer 112 includes a recess portion 121 and an extension portion 123. After etching the protective layer 120, a second opening 172 is formed in the protective layer 120, and the inner sidewall 162 of the first portion 116 is still covered with the protective layer 120.

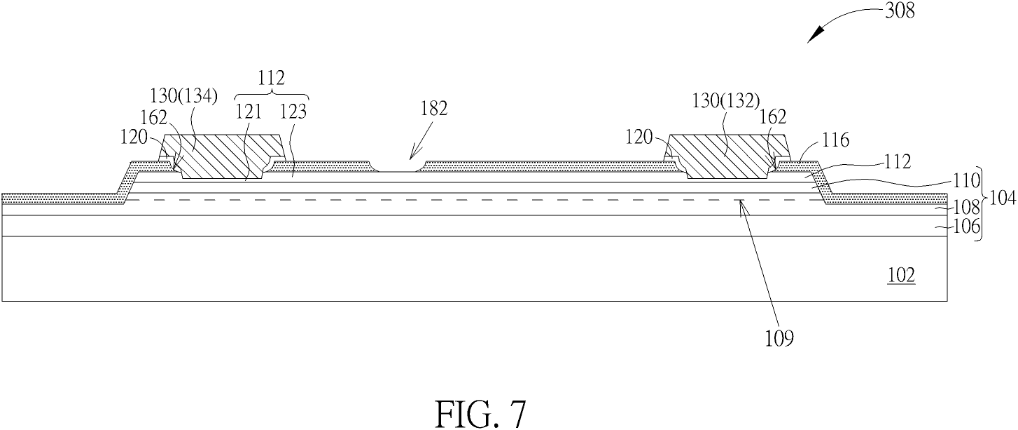

Next, in step 410 of the manufacturing method 400, the electrode structure is disposed so that the protective layer is sandwiched between the electrode structure and the inner sidewall. Referring to the cross-sectional view 308 of FIG. 7, electrode structures 130, such as a drain electrode 132 and a source electrode 134, are filled into the openings in the protective layer 120, so that the protective layer 120 is sandwiched between the electrode structures 130 and the inner sidewall 162. The method of forming the electrode structures 130 may include first disposing a conductive layer (not shown) on the first portion 116. The material of the conductive layer includes metal, alloy or stacked layers thereof, such as, but not limited thereto, Ti/Al, Ti/Al/Ti/TiN, Ti/Al/Ti/Au, Ti/Al/Ni/Au or Ti/Al/Mo/Au. Then, removing a portion of the conductive layer to form the electrode structure 130. In one embodiment, the method of removing a portion of the conductive layer includes etching method. In an etching process, the portion of the conductive layer is etched to form the electrode structure 130. In the etching process for forming the electrode structures 130, the protective layer 120 not covered with the electrode structure 130 (the conductive layer) is removed, and the cap layer 112 and the first portion 116 can also be partially etched, so that the thickness of the first portion 116 not covered with the electrode structures 130 is reduced.

Then, in step 412 of the manufacturing method 400, a heat treatment process is performed, where the temperature of the heat treatment process is higher than the first reaction temperature and lower than the second reaction temperature. Referring to cross-sectional view 308 of FIG. 7, the heat treatment process is, for example, a process with a process temperature higher than 600° C., or a process with a process temperature lower than 900° C. according to some embodiments. An annealing process performed in the temperature range of the heat treatment process and in an inert atmosphere can transform contact between the electrode structure 130 and at least one of the underlying barrier layer 110 and the channel layer 108 to ohmic contact. Since the first material of the insulating structure 114 is capable of reacting the metal material of the electrode structure 130 at a reaction temperature (i.e., the first reaction temperature), which is lower than or equal to the temperature of the heat treatment process, the protective layer 120 with suitable material can be selected and disposed between the electrode structure 130 and the first portion 116 to avoid the reaction therebetween. The suitable material of the protective layer 120 is selected from a material which is capable of reacting with the metal material of the electrode structure 130 at a reaction temperature (i.e., the second reaction temperature), which is set to be higher than the temperature of the heat treatment process, or even there is no reaction between the second material of the protective layer 120 and the metal material of the electrode structure 130. Therefore, the chemical reaction between the electrode structure 130 and the first portion 116 of the insulating structure 114 can be avoided, thereby preventing the increasing in the electrical resistivity of the electrode structure 130. In addition, during the heat treatment process, the metal composition (e.g., aluminum) in the electrode structure 130 can diffuse into the recess portion 121 of the cap layer 112, so that the recess portion 121 includes the metal composition in the electrode structure 130, and the electrical resistivity of the recess portion 121 is lower than the electrical resistivity of the extension portion 123 nearby. Then, photolithography and etching processes are performed to form a first contact opening 182 such as a gate contact opening in the first portion 116, and the first contact opening 182 exposes a portion of the cap layer 112. The etching process for forming the first contact opening 182 includes a dry etching or wet etching process. Taking the wet etching process as an example, the inner sidewall of the first contact opening 182 is inclined rather than vertical due to the lateral etching characteristics of the wet etching process. In this way, the subsequently deposited film can have better coverage ability (such as step coverage ability) in the subsequent film deposition process, thus improving the device reliability.

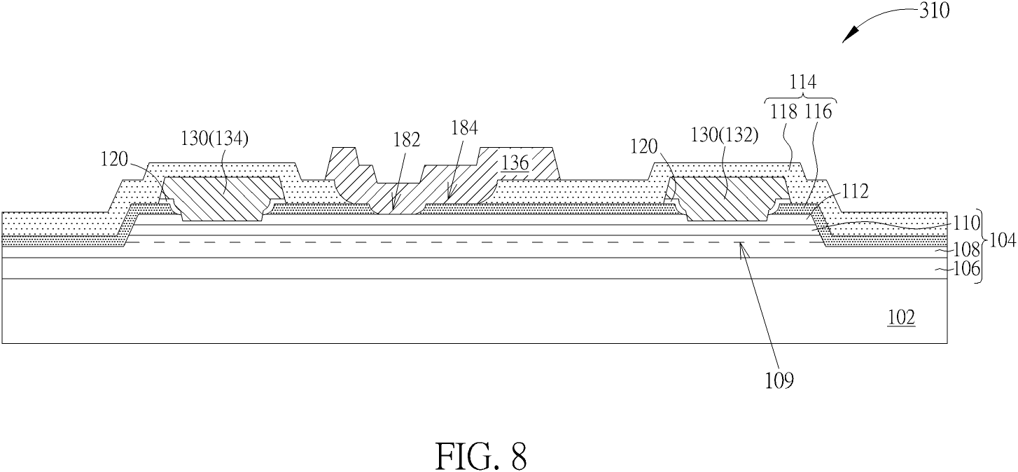

After the stage of the manufacturing process shown in FIG. 7 is completed, referring to a cross-sectional view 310 of FIG. 8, a deposition process such as a vapor deposition process is then performed to form a second portion 118 conformally covering the first portion 116. In one embodiment, the material of the second portion 118 is different from the material of the cap layer 112. The material of the second portion 118 is the same as or different from the material of the first portion 116. For example, the material of the second portion 118 includes insulating materials, such as Si₃N₄, AlN, or other insulating nitride materials, Al₂O₃, SiO₂, or other insulating oxide materials, or SiON as an insulating oxide material or an insulating nitride material, but not limited thereto. In addition, the second portion 118 is not limited to a single-layer structure, but may also be a multi-layer stacked structure. Then, an etching process, such as a dry etching or wet etching process, is performed on the second portion 118 to form a second contact opening 184, such as a gate contact opening, in the second portion 118. After the etching process is performed on the second portion 118, the first portion 116 and the second portion 118 together can show a step profile. In some embodiments, the width of the first contact opening 182 is smaller than the width of the second contact opening 184. In some embodiments, the width of the first contact opening 182 is larger than the width of the second contact opening 184, such as, the second portion 118 is conformally formed on the first portion 116 and extends into the first contact opening 182, thus forming the second contact opening 184 in the first contact opening 182.

Then, by performing deposition and patterning processes, a conductive layer such as a gate electrode 136 is formed on the second portion 118, and the gate electrode 136 can fill up the first contact opening 182 and the second contact opening 184. The gate electrode 136 can extend outward from the second contact opening 184 and has an asymmetric cross-section. The material of the gate electrode 136 may include metal, alloy, semiconductor, or stacked layers thereof. For example, the gate electrode 136 may include gold (Au), nickel (Ni), platinum (Pt), palladium (Pd), iridium (Ir), titanium (Ti), chromium (Cr), tungsten (W), aluminum (Al), copper (Cu), molybdenum (Mo), other suitable conductive materials, or a combination thereof.

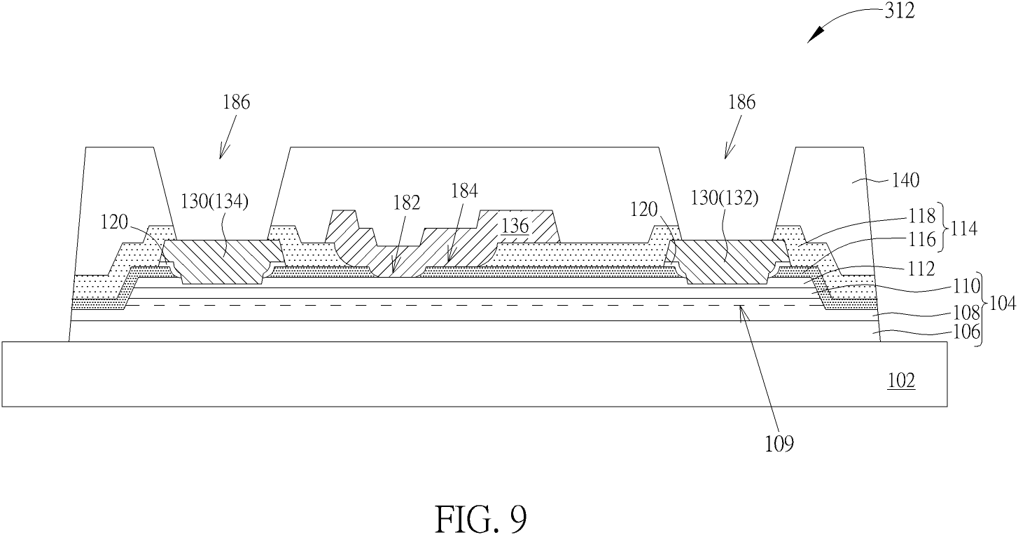

After the stage of manufacturing process shown in FIG. 8, referring to the cross-sectional view 312 of FIG. 9, a third insulating layer such as a dielectric interlayer 140 is formed to cover the protective layer 120, the electrode structure 130, the second insulating layer 118, and the gate electrode 136. Then, third contact openings 186, such as bond pad contact openings, are formed in the dielectric interlayer 140 to expose the underlying drain electrode 132 and the source electrode 134, respectively. The material of the dielectric interlayer 140 includes insulating materials, such as Si₃N₄, AlN, or other insulating nitride materials, Al₂O₃, SiO₂, or other insulating oxide materials, or SiON as an insulating oxide material or an insulating nitride material, but not limited thereto.

Then, at least two bond pad structures (not shown), which are disposed in the third contact openings 186 of the dielectric interlayer 140, are formed and electrically connected to the drain electrode 132 and the source electrode 134, respectively. The top surfaces of the bond pad structures are exposed from the dielectric interlayer 140 and serve as regions through which the semiconductor device 100 and external devices are electrically connected. Another bond pad structure (not shown) may also be formed to be electrically connected to the gate electrode 136. Thus, the semiconductor device 100 shown in FIG. 1 can be obtained.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor stack;
an insulating structure, disposed on the semiconductor stack and including a first portion, wherein the first portion comprises a first opening exposing an inner sidewall of the insulating structure;
an electrode structure, comprising a metal material; and
a protective layer, disposed between the inner sidewall and the electrode structure and including a second opening;
wherein the electrode structure is disposed in the first opening and in contact with the protective layer, and the electrode structure is electrically connected to the semiconductor stack through the second opening; and
wherein the insulating structure comprises a first material, and the protective layer comprises a second material.

2. The semiconductor device according to claim 1, wherein the electrode structure fills the second opening.

3. The semiconductor device according to claim 1, wherein a portion of the protective layer is located outside the first opening and on an upper surface of the first portion of the insulating structure.

4. The semiconductor device according to claim 3, wherein the portion of the protective layer is between the upper surface of the first portion of the insulating structure and the electrode structure.

5. The semiconductor device according to claim 4, wherein the electrode structure is completely separated from and not in contact with the first portion of the insulating structure by the protective layer.

6. The semiconductor device according to claim 1, wherein the protective layer conformally covers a top surface of the first portion and the inner sidewall of the insulating structure.

7. The semiconductor device according to claim 1, wherein the first material comprises an oxide material, and/or the second material comprises a nitride material.

8. The semiconductor device according to claim 7, wherein the nitride material comprises a metal nitride material.

9. The semiconductor device according to claim 1, wherein the first material and the metal material are capable of reacting at a first reaction temperature, and the second material and the metal material are capable of reacting at a second reaction temperature, wherein the second reaction temperature is higher than the first reaction temperature.

10. The semiconductor device according to claim 1, wherein the first material and the metal material are capable of reacting at a first reaction temperature, and the second material and the metal material are devoid of reacting with each other.

11. The semiconductor device according to claim 1, wherein the first portion of the insulating structure further comprises:
an end portion, located between the semiconductor stack and the protective layer; and
an extension portion, extending from one side of the end portion, wherein a top surface of the end portion is higher than a top surface of the extension portion.

12. The semiconductor device according to claim 1, further comprising a cap layer disposed between the insulating structure and the semiconductor stack, wherein the second opening exposes the cap layer.

13. The semiconductor device according to claim 1, wherein the electrode structure comprises a source electrode and a drain electrode; and wherein the semiconductor device further comprises a gate electrode disposed between the source electrode and the drain electrode.

14. A method of manufacturing a semiconductor device, comprising:
providing a semiconductor stack;
disposing a first insulating layer on the semiconductor stack, wherein the first insulating layer comprises a first opening exposing an inner sidewall of the first insulating layer;
filling a protective layer into the first opening to cover the inner sidewall;
etching the protective layer to remove a portion of the protective layer in the first opening to form a second opening;
disposing an electrode structure so that the protective layer is sandwiched between the electrode structure and the inner sidewall; and
performing a heat treatment process at a treatment temperature,
wherein the first insulating layer comprises a first material, the protective layer comprises a second material, and the electrode structure comprises a metal material.

15. The manufacturing method of semiconductor device according to claim 14, wherein, the first material and the metal material are capable of reacting at a first reaction temperature, and the treatment temperature is higher than the first reaction temperature.

16. The manufacturing method of semiconductor device according to claim 15, wherein, the second material and the metal material are capable of reacting at a second reaction temperature, and the second reaction temperature is higher than the first reaction temperature, or the second material and the metal material are devoid of reacting with each other.

17. The method of manufacturing the semiconductor device according to claim 14, wherein the step of disposing the electrode structure comprises:
disposing a conductive layer on the first insulating layer; and
performing an etching process to etch the conductive layer and the first insulating layer.

18. The method of manufacturing the semiconductor device according to claim 14, wherein the second opening exposes a portion of the semiconductor stack, the electrode structure is located in the second opening, and after the heat treatment process, there is ohmic contact between the electrode structure and the semiconductor stack.

19. The method of manufacturing the semiconductor device according to claim 14, wherein, after performing the heat treatment process, the method further comprises:
disposing a second insulating layer to cover the semiconductor stack, the first insulating layer, the protective layer, and the electrode structure;
etching the second insulating layer to form a contact hole;
disposing a conductive layer on the second insulating layer, and the conductive layer filled into the contact hole; and
disposing a third insulating layer to cover the protective layer, the electrode structure, the second insulating layer, and the conductive layer.

20. The method of manufacturing the semiconductor device according to claim 14, wherein the method further comprises:
disposing a cap layer on the semiconductor stack before disposing the first insulating layer;
exposing a portion of the cap layer before etching the protective layer; and
etching the portion of the cap layer before disposing the electrode structure,
wherein the portion of the cap layer comprises a metal composition of the electrode structure after performing the heat treatment process.
